(19) United States
(12) Patent Application Publication
(10) Pub. No.: US 2026/0231386 A1
(43) Pub. Date: Aug. 6, 2026

(54) INTEGRATED CIRCUIT STRUCTURE AND METHOD FOR FORMING INTERCONNECTION STRUCTURE OF MEMORY CELL

(71) Applicant: Taiwan Semiconductor Manufacturing Company, Ltd., Hsinchu (TW)

(72) Inventors: Chia Chen LEE, Hsinchu (TW); Chia-Tien WU, Hsinchu (TW); Yi-Hsun CHIU, Hsinchu (TW); Kao-Cheng LIN, Hsinchu (TW); Ching-Wei TSAI, Hsinchu (TW); Ching-Chang WU, Hsinchu (TW); Yi-Bo LIAO, Hsinchu (TW)

(73) Assignee: Taiwan Semiconductor Manufacturing Company, Ltd., Hsinchu (TW)

(21) Appl. No.: 19/046,949

(22) Filed: Feb. 6, 2025

(51) Int. Cl. H10B 10/00

(52) U.S. Cl. CPC H10B 10/125

(57) ABSTRACT

An integrated circuit structure includes a memory cell and an interconnection structure electrically connected to the memory cell. A first level metal layer is disposed on the memory cell, and the first level metal layer includes a first bit-line conductor and a second bit-line conductor arranged along a first routing direction. A second level metal layer includes a first word-line conductor extending along a second routing direction different from the first routing direction. A via line is disposed on the first word-line conductor and extending along the second routing direction. A third level metal layer is disposed on the second level metal layer, and the third-level metal layer includes a second word-line conductor extending along the second routing direction, wherein the second word-line conductor, the via line and the first word-line conductor overlap along the second routing direction to form a double-layered word-line conductor.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down has also increased the complexity of processing and manufacturing ICs and, for these advances to be realized, similar developments in IC processing and manufacturing are needed. For example, as multilayer interconnect (MLI) features become more compact with ever-shrinking IC feature size, interconnects of the MLI features are exhibiting increased resistance and exhibiting increased capacitance, which presents performance, yield, and cost challenges. It has been observed that these higher resistances and/or higher capacitances exhibited by interconnects in advanced IC technology nodes can significantly delay (and, in some situations, prevent) signals from being routed efficiently to and from IC devices, such as transistors, negating any improvements in performance of such IC devices in the advanced technology nodes. Performance of advanced memories, such as static random-access memory (“SRAM”), is especially sensitive to these delays, where the advanced memories are requiring ever faster speeds (e.g., fast write/read). Accordingly, although existing MLI features for memory-based ICs and their interconnects have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a circuit diagram of a single-port static random-access memory (SRAM) cell according to one embodiment.

FIG. 2 shows an equivalent circuit diagram of the SRAM cell of FIG. 1.

FIG. 3 shows a front-side diagrammatic plan view of an exemplified SRAM cell according to FIG. 1.

FIG. 4 shows a cross section view of the SRAM cell of FIG. 3 along a cutting line C1 according to one embodiment.

FIG. 5A and FIG. 6A respectively show a top view of the M0 metal layer of FIG. 3 according to different embodiments.

FIG. 5B and FIG. 6B respectively show a top view of the first level metal layer of FIG. 3 according to different embodiments.

FIG. 7 shows a top view of the second level metal layer of FIG. 3 according to one embodiment.

FIG. 8 shows a top view of the third level metal layer of FIG. 3 according to one embodiment.

FIG. 9 shows an interconnection structure of a memory cell in the integrated circuit structure according to one embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides many different embodiments. The configuration of the metal layers of the interconnection structure disclosed herein can improve memory performance, such as static random-access memory (SRAM) performance, and/or logic performance. For example, in some embodiments, the bit-line conductors are disposed in the first level metal layer, the first word-line conductor is disposed in the second level metal layer, and the second word-line conductors are disposed in the third level metal layer. The bit-line conductors are arranged along the first routing direction, and the first word-line conductors, via line and the second word-line conductors overlap and extend along the second routing direction to form a double-layered word-line conductor.

The double-layered word-line conductor is used to reduce the resistance of the word line, and the double-layered word-line conductor is arranged above the bit-line conductors, so that the overlapping areas of the first word-line conductor, the second word-line conductor and the bit-line conductors are reduced and the parasitic capacitance of the memory cell is reduced.

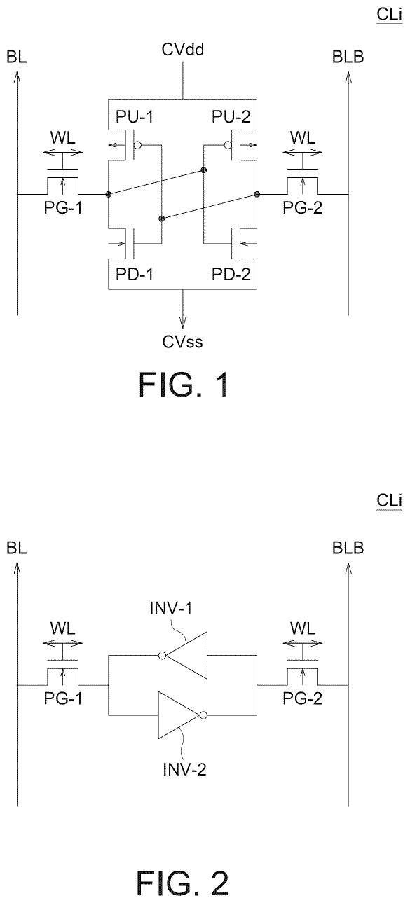

Referring to FIG. 1, FIG. 1 shows a circuit diagram of a single-port static random-access memory (SRAM) cell CLi according to one embodiment. The SRAM cell CLi includes a first pass-gate transistor PG-1, a first pull-up transistor PU-1, a first pull-down transistor PD-1, a second pass-gate transistor PG-2, a second pull-up transistor PU-2, and a second pull-down transistor PD-2.

A drain node of the first pass-gate transistor PG-1, a drain node of the first pull-up transistor PU-1, a drain node of the first pull-down transistor PD-1, a gate node of the second pull-up transistor PU-2, and a gate node of the second pull-down transistor PD-2 are electrically connected together to form a storage node.

A drain node of the second pass-gate transistor PG-2, a drain node of the second pull-up transistor PU-2, a drain node of the second pull-down transistor PD-2, a gate node of the first pull-up transistor PU-1, and a gate node of the first pull-down transistor PD-1 are electrically connected together to form another storage node.

A source node of the first pass-gate transistor PG-1 is electrically connected to a first bit line BL. A source node of the first pull-up transistor PU-1 and a source node of the second pull-up transistor PU-2 are electrically connected to a power source voltage CVdd. A source node of the first pull-down transistor PD-1 and a second pull-down transistor PD-2 are electrically connected to a common voltage CVss. A source node of the second pass-gate transistor PG-2 is electrically connected to a second bit line BLB, which is separate from the first bit line BL. A gate node of the first pass-gate transistor PG-1 and a gate node of the second pass-gate transistor PG-2 are electrically connected to a word line WL.

Referring to FIG. 1, FIG. 1 shows a circuit diagram of a single-port static random-access memory (SRAM) cell CLi according to one embodiment. The SRAM cell CLi includes a first pass-gate transistor PG-1, a first pull-up transistor PU-1, a first pull-down transistor PD-1, a second pass-gate transistor PG-2, a second pull-up transistor PU-2, and a second pull-down transistor PD-2.

A drain node of the first pass-gate transistor PG-1, a drain node of the first pull-up transistor PU-1, a drain node of the first pull-down transistor PD-1, a gate node of the second pull-up transistor PU-2, and a gate node of the second pull-down transistor PD-2 are electrically connected together to form a storage node.

A drain node of the second pass-gate transistor PG-2, a drain node of the second pull-up transistor PU-2, a drain node of the second pull-down transistor PD-2, a gate node of the first pull-up transistor PU-1, and a gate node of the first pull-down transistor PD-1 are electrically connected together to form another storage node.

A source node of the first pass-gate transistor PG-1 is electrically connected to a first bit line BL. A source node of the first pull-up transistor PU-1 and a source node of the second pull-up transistor PU-2 are electrically connected to a power source voltage CVdd. A source node of the first pull-down transistor PD-1 and a second pull-down transistor PD-2 are electrically connected to a common voltage CVss. A source node of the second pass-gate transistor PG-2 is electrically connected to a second bit line BLB, which is separate from the first bit line BL. A gate node of the first pass-gate transistor PG-1 and a gate node of the second pass-gate transistor PG-2 are electrically connected to a word line FM2_WL.

These transistors are formed by either FinFET transistor or vertically stacked multiple channels gate-all-around (GAA) horizontal nano-sheets transistor.

Referring to FIG. 2, FIG. 2 shows an equivalent circuit diagram of the SRAM cell CLi of FIG. 1. The first pull-up transistor PU-1 and the first pull-down transistor PD-1 of FIG. 1 form a first inverter INV-1. The second pull-up transistor PU-2 and the second pull-down transistor PD-2 of FIG. 1 form a second inverter INV-2. The first inverter INV-1 and the second inverter INV-2 are cross-coupled.

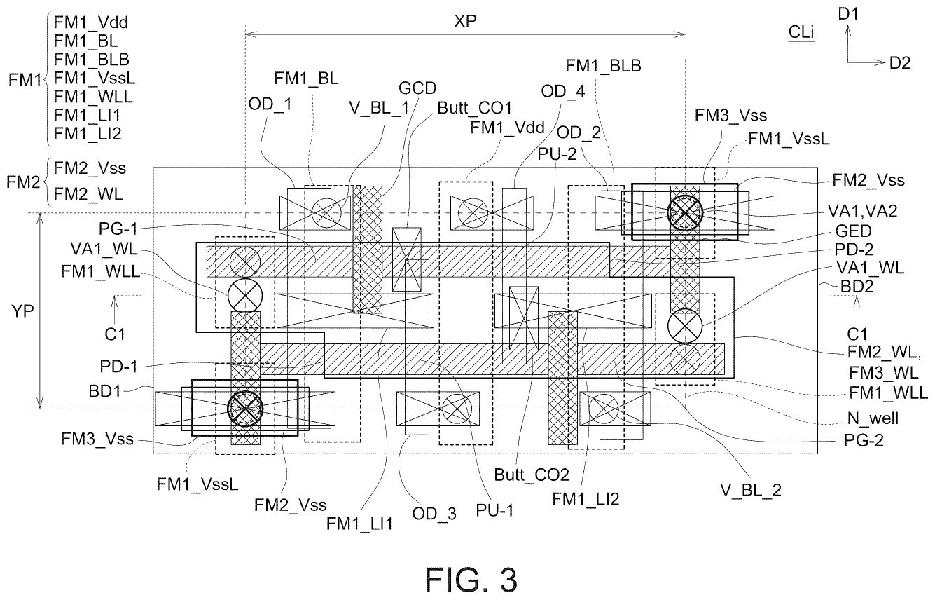

Referring to FIG. 3, FIG. 3 shows a diagrammatic plan view of an exemplified SRAM cell CLi according to FIG. 1. The SRAM cell CLi includes a first active region OD_1, a second active region OD_2, a third active region OD_3, a fourth active region OD_4, the first pull-up transistor PU-1, the second pull-up transistor PU-2, the first pass-gate transistor PG-1, the second pass-gate transistor PG-2, the first pull-down transistor PD-1 and the second pull-down transistor PD-2. The third active region OD_3 and the fourth active region OD_4 are located between the first active region OD_1 and the second active region OD_2.

The first active region OD_1 to the fourth active region OD_4 follow a first routing direction D1. The first pull-up transistor PU-1 is formed upon the third active region OD_3. The second pull-up transistor PU-2 is formed upon the fourth active region OD_4.

The first pass-gate transistor PG-1 is formed upon the first active region OD_1. The second pass-gate transistor PG-2 is formed upon the second active region OD_2. The first pull-down transistor PD-1 is formed upon the first active region OD_1. The second pull-down transistor PD-2 is formed upon the second active region OD_2. The first pull-up transistor PU-1 is formed upon the third active region OD_3. The second pull-up transistor PU-2 is formed upon the fourth active region OD_4.

The SRAM cell CLi has a Y-pitch YP along the first routing direction D1 and a X-pitch XP along the second routing direction D2. The Y-pitch YP and the X-pitch XP are more than 1X contacted poly pitch (CPP) or 1X transistor gate pitch. For example, The X-pitch XP is 4X contacted poly pitch (CPP) or 4X transistor gate pitch. The contacted poly pitch (CPP) is the minimum distance between two parallel poly. The SRAM cell CLi is rectangular shaped and the ratio of X-pitch XP and Y-pitch YP is from about 1.5 to about 3. That is, the Y-pitch YP is reduced to shrink the component size.

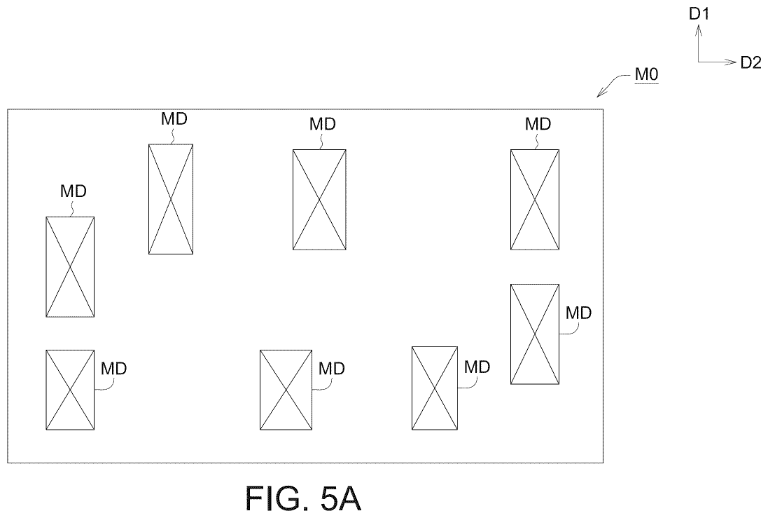

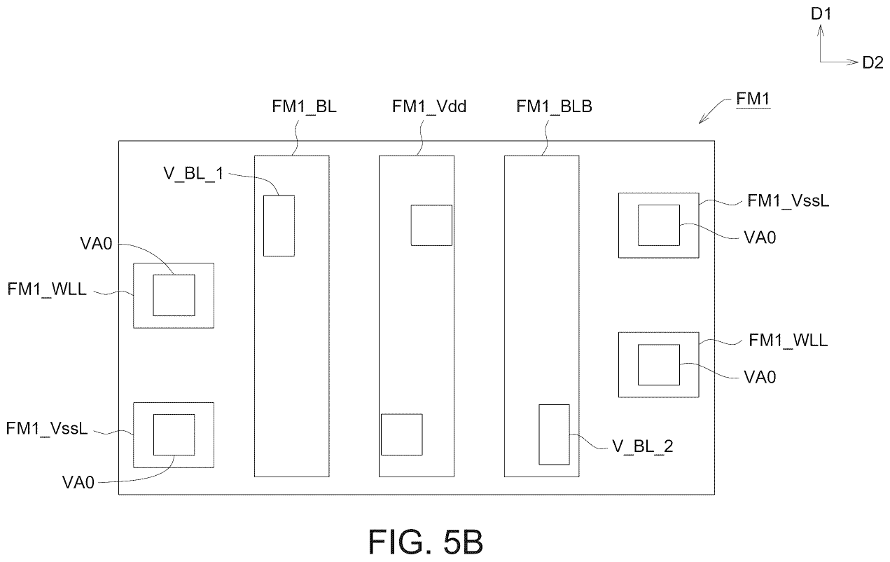

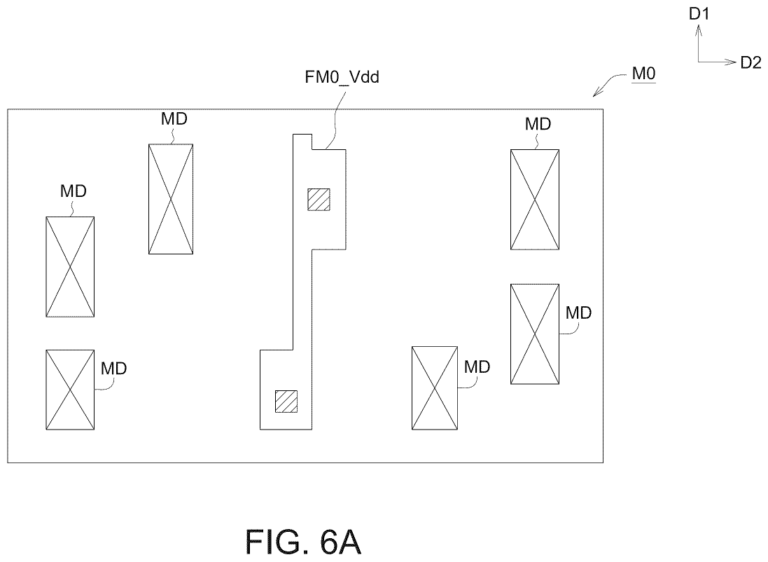

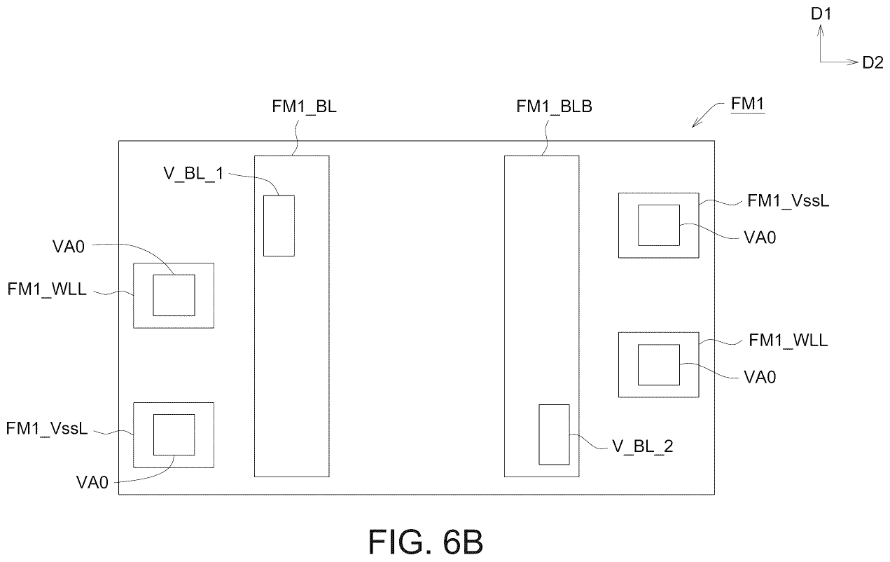

The SRAM cell CLi includes a contact metal layer M0, a first level metal layer FM1, a second level metal layer FM2 and a third level metal layer FM3. The contact metal layer M0, as shown in FIG. 5A and FIG. 6A, includes a plurality of source/drain contacts MD for electrically connecting to the source/drain region of the first pull-down transistor PD-1, the source/drain region of the second pull-down transistor PD-2, the source/drain region of the first pull-up transistor PU-1, the source/drain region of the second pull-up transistor PU-1, the source/drain region of the first pass-gate transistor PG-1, the source/drain region of the second pass-gate transistor PG-2 and/or the gate regions of the first and second pass-gate transistors PG-1 and PG-2. The first level metal layer FM1, as shown in FIGS. 3 and 5B, includes a power supply voltage conductor FM1_Vdd, a first bit-line conductor FM1_BL, a second bit-line conductor FM1_BLB, two common voltage landing pads FM1_VssL, two word-line landing lines FM1_WLL, a first local connection line FM1_LI1 and a second local connection line FM1_LI2. A first contact Butt_CO1 is located under the first local connection line FM1_LI1 and connected to the first local connection line FM1_LI1. A second contact Butt_CO2 is located under the second local connection line FM1_LI2 and connected to the second local connection line FM1_LI2. The power supply voltage conductor FM1_Vdd is located in the middle of the SRAM cell CLi and shared with another adjacent SRAM cell CLi, and electrically connected to a source node of the first pull-up transistor PU-1 and a source node of the second pull-up transistor PU-2. The two common voltage landing pads FM1_VssL are located at two boundaries BD1 and BD2 of the SRAM cell CLi and electrically connected to a source node of the first pull-down transistor PD-1 and a source node of the second pull-down transistor PD-2. The two word-line landing lines FM1_WLL are located at two boundaries BD1 and BD2 of the SRAM cell CLi and electrically connected to a gate node of the first pass-gate transistor PG-1 and a gate node of the second pass-gate transistor PG-2. The first local connection lines FM1_LI1 and the first contact Butt_CO1 are used to make an electrical connection among a drain node of the first pull-up transistor PU-1, a drain node of the first pull-down transistor PD-1, a drain node of the first pass-gate transistor PG-1, a gate node of the second pull-up transistor PU-2 and a gate node of the second pull-down transistor PD-2. The second local connection lines FM1_LI2 and the second contact Butt_CO2 are used to make an electrical connection among a drain node of the second pull-up transistor PU-2, a drain node of the second pull-down transistor PD-2, a drain node of the second pass-gate transistor PG-2, a gate node of the first pull-up transistor PU-1 and a gate node of the first pull-down transistor PD-1. The first bit-line conductor FM1_BL is electrically connected to a source node of the first pass-gate transistor PG-1, and the second bit-line conductor FM1_BLB is electrically connected to a source node of the second pass-gate transistor PG-2, such that the first pass-gate transistor PG-1 and the second pass-gate transistor PG-2 are electrically connected to individual first and second bit-line conductors FM1_BL and FM1_BLB.

In another embodiment, the first level metal layer FM1, as shown in FIGS. 3 and 6B, includes a first bit-line conductor FM1_BL, a second bit-line conductor FM1_BLB, two common voltage landing pads FM1_VssL, two word-line landing lines FM1_WLL, a first local connection line FM1_LI1 and a second local connection line FM1_LI2, but does not include a power supply voltage conductor FM1_Vdd because the power supply voltage conductor FM0_Vdd in the contact metal layer M0 of FIG. 6A replaces the power supply voltage conductor FM1_Vdd in first level metal layer FM1 of FIG. 3.

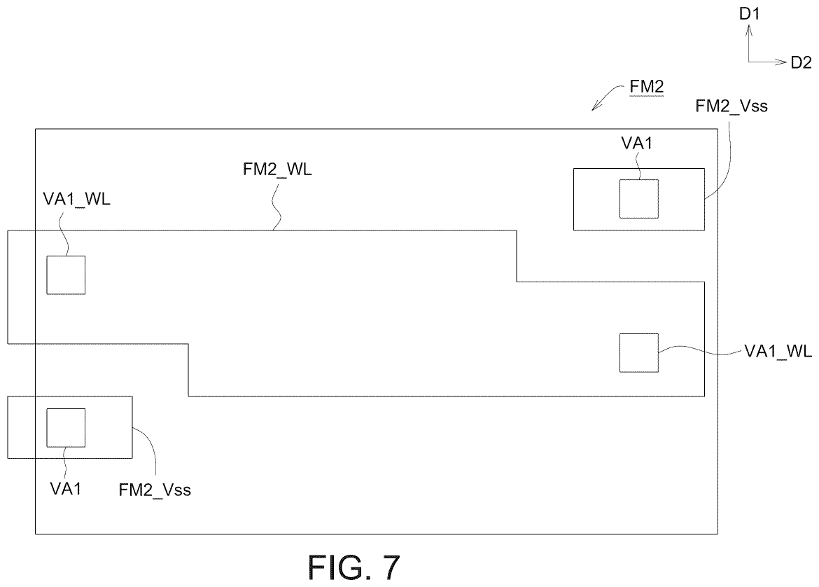

The second level metal layer FM2 is located upon the first level metal layer FM1. The second level metal layer FM2, as shown in FIGS. 3 and 7, includes a first word-line conductor FM2_WL and two common voltage conductors FM2_Vss. The first word-line conductor FM2_WL follows a second routing direction D2 substantially perpendicular to the first routing direction D1. The common voltage conductors FM2_Vss follow the second routing direction D2. The two common voltage conductors FM2_Vss are located at two boundaries BD1 and BD2 of the SRAM cell CLi and electrically connected to the individual common voltage landing pads FM1_VssL through vias VA1. In addition, the first word-line conductor FM2_WL is electrically connected to the two word-line landing lines FM1_WLL through vias VA1_WL.

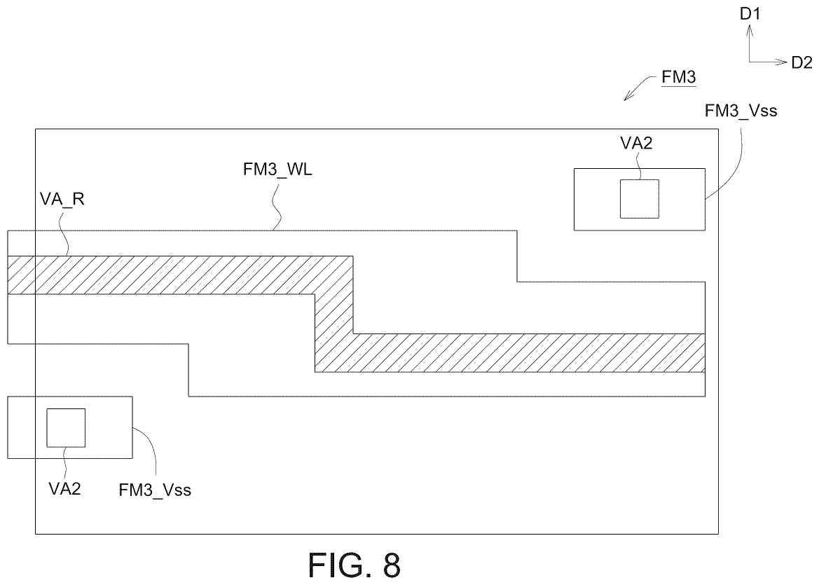

The third level metal layer FM3 is located upon the second level metal layer FM2. The third level metal layer FM3, as shown in FIGS. 3 and 8, includes a second word-line conductor FM3_WL and two common voltage conductor lines FM3_Vss at two boundaries BD1 and BD2 of the SRAM cell CLi. The two common voltage conductor lines FM3_Vss follow the second routing direction D2. The common voltage conductor lines FM3_Vss are electrically connected to the individual common voltage conductors FM2_Vss through vias VA2. In addition, the second word-line conductor FM3_WL is electrically connected to the first word-line conductor FM2_WL through a via line VA_R. The via line VA-R is also called a wall line connected between the first word-line conductor FM2_WL and the second word-line conductor FM3_WL so as to reduce the resistance of the word-line conductor.

The via line VA_R is disposed on the first word line FM2_WL along the second routing direction D2, and the via line VA_R overlaps the first word line FM2_WL. The second word line FM3_WL extends along the second routing direction D2, and the second word line FM3_WL overlaps the via line VA_R and the first word line FM2_WL.

In the SRAM cell CLi of FIG. 3, the first bit-line conductor FM1_BL is shifted from the first active region OD_1, and the second bit-line conductor FM1_BLB is shifted from the second active region OD_2. Only part of the first bit-line conductor FM1_BL overlaps with the first active region OD_1. Only part of the second bit-line conductor FM1_BLB overlaps with the second active region OD_2. A contact V_BL_1 extends to the outside of the first active region OD_1 and does not fully cover by the first bit-line conductor FM1_BL. A contact V_BL_2 extends to the outside of the second active region OD_2 and does not fully cover by the second bit-line conductor FM1_BLB.

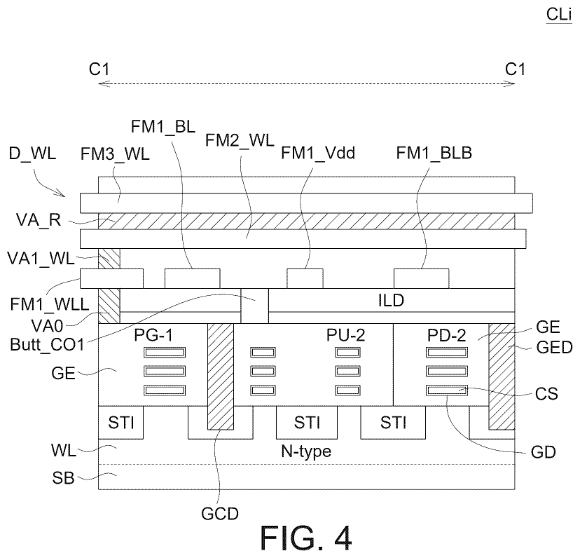

Referring to FIG. 4, FIG. 4 shows a cross section view of the SRAM cell CLi along a cutting line C1 according to one embodiment. The first contact Butt_CO1 is formed upon a dummy dielectric gate structure (not shown) used for isolating the second pull-up transistor PU-2 to another adjacent SRAM cell CLi. The second contact Butt_CO2 is formed upon a dummy dielectric gate structure (not shown) used for isolating the first pull-up transistor PU-1 to another adjacent SRAM cell CLi.

As shown in the FIG. 4, a substrate SB, a N-well region WL, a plurality of channel sheets CS, a plurality of source/drain regions S/D, a gate electrode GE of a pull-down transistor PD-2 and a pull-up transistor PU-2, a gate electrode GE of a pass-gate transistor PG-1, a plurality of gate dielectric layers GD, an interlayer dielectric layer ILD, a via VA1_WL, a via line VA_R, a first level metal layer FM1, a second level metal layer FM2 and a third level metal layer FM3 of the SRAM cell CLi are shown. The gate electrode GE of the pass-gate transistor PG-1 spans perpendicularly across the channel sheets CS of the semiconductor layers, and the gate electrode GE of the pull-down transistor PD-2 and the pull-up transistor PU-2 spans perpendicularly across the channel sheets CS of the semiconductor layers.

In one embodiment, as shown in the FIG. 4, the substrate SB includes silicon, such as a silicon wafer. Alternatively, the substrate SB may include another elementary semiconductor, such as Germanium (Ge); a compound semiconductor, such as Silicon carbide, Gallium Arsenide (GaAs), Gallium Phosphide (GaP), Indium Phosphide (InP), Indium Arsenide (InAs), and/or Indium Antimonide (In Sb); an alloy semiconductor, such as Silicon Germanium (SiGe), GaAsP, AlInAs, AlGaAs, GaInAs, GaInP, and/or GaInAsP; or combinations thereof. Alternatively, the substrate SB is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

In one embodiment, the well region is, for example, a P-type well and is disposed in the n-type substrate. In one embodiment, as shown in the FIG. 4, the well region WL is, for example, a N-type well and is disposed in the P-type substrate SB. In the present embodiment, the N-well region WL includes the same semiconductor material(s) as the substrate SB. The N-well region WL may be doped with n-type dopants, such as phosphorus, arsenic, other n-type dopant, or combinations thereof, configured for the PMOS and NMOS. The dopant concentration in the N-well region WL may be in a range of about 1E16 atom/cm³ to about 1E19 atom/cm³ in some embodiments, depending on well resistance requirements.

As shown in the FIG. 4, the vertically sheet pitch of the channel region of the vertically stacked channel sheets CS is, for example, within a range of 12 nm to 20 nm. The channel (sheet) thickness is within a range of 4 nm to 8 nm. The channel (sheet) space is within a range of 4 nm to 20 nm.

As shown in the FIG. 4, the stack of channel sheets CS serves as the transistor channels for the respective GAA devices. The channel sheets CS may include single crystalline silicon. Alternatively, the channel sheets CS may comprise Germanium, Silicon Germanium, or another suitable semiconductor material(s). In the present embodiment, the channel sheets CS are undoped. For example, the dopant concentration in the channel sheets CS may be lower than about 1E16 atom/cm³. In some embodiments, the channel sheets CS may be unintentionally doped with a very low concentration of dopants. For example, the dopant concentration in the channel sheets CS may be lower than about 5E16 atom/cm³. Initially, the channel sheets CS are formed as part of a semiconductor layer stack that includes the channel sheets CS and some sacrificial semiconductor layers of a different material. During a gate replacement process, the semiconductor layer stack is selectively etched to remove the sacrificial semiconductor layers, leaving the channel sheets CS suspended over the substrate SB and between the respective source/drain regions. In various embodiments, the number of channel sheets CS in a GAA device may be in a range of 2 to 10, such as 3 or 4.

As shown in the FIG. 4, the gate dielectric layers GD surround the gate electrodes GE. Each of the gate dielectric layers GD includes oxide with Nitrogen doped dielectric combined with metal content high-K dielectric (K is larger than 3). The thickness of each of the gate dielectric layers GD is 0.5 nm to 3 nm. A material of the gate dielectric layers GD is Tantalum oxide, such as Ta2O5, Aluminum oxide, such as Al2O3, Hf content oxide, Titanium content oxide, Zirconium content oxide, Lanthanum content oxide, high-K material (K is equal to or larger than 9), the like or a combination thereof.

As shown in the FIG. 4, the gate dielectric layers GD surround the gate electrodes GE. Each of the gate dielectric layers GD includes oxide with Nitrogen doped dielectric combined with metal content high-K dielectric (K is larger than 3). The thickness of each of the gate dielectric layers GD is 0.5 nm to 3 nm. A material of the gate dielectric layers GD is Tantalum oxide, such as Ta₂O₅, Aluminum oxide, such as Al₂O₃, Hf content oxide, Titanium content oxide, Zirconium content oxide, Lanthanum content oxide, high-K material (K is equal to or larger than 9), the like or a combination thereof.

As shown in the FIG. 4, each of the gate dielectric layers GD wrap around each of the channel sheets CS. Each of the gate dielectric layers GD may include a high-k dielectric material such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba, Sr)TiO₃ (BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k≈3.9). The gate dielectric layers GD may be formed by chemical oxidation, thermal oxidation, atomic layer deposition (ALD), chemical vapor deposition (CVD), and/or other suitable methods, and may have a thickness in a range of about 0.5 nm to about 3 nm. In some embodiments, the gate electrodes GE further include an interfacial layer between the gate dielectric layers GD and the channel sheets SC. The interfacial layer may include silicon dioxide, silicon oxynitride, or other suitable materials. In some embodiments, each of the gate electrodes GE includes an n-type work function layer for NMOS transistor, and each of the gate electrodes GE includes a p-type work function layer for PMOS transistor. For example, an n-type work function layer may comprise a metal with sufficiently low effective work function such as titanium, aluminum, tantalum carbide, tantalum carbide nitride, tantalum silicon nitride, or combinations thereof. For example, a p-type work function layer may comprise a metal with a sufficiently large effective work function, such as titanium nitride, tantalum nitride, ruthenium, molybdenum, tungsten, platinum, or combinations thereof. Since the gate electrodes GE includes a high-k dielectric layer and metal layer(s), it is also referred to as a high-k metal gate.

As shown in the FIG. 4, the gate cut dielectric layer GCD is disposed between the end of the gate electrodes GE of the pull-up transistor PU-2 and the end of the gate electrodes GE of the pass gate transistor PG-1. As shown in the FIG. 3, the gate cut dielectric layer GCD is disposed between the end of the gate electrodes GE of the pull-up transistor PU-1 and the end of the gate electrodes GE of the pass gate transistor PG-2. The gate cut dielectric layers GCD provide isolation functions for nearby transistors. In an embodiment, the gate cut dielectric layers GCD include a high-k material, such as selected from a group consisting of Si3N4, nitrogen-containing oxide, carbon-containing oxide, dielectric metal oxide such as HfO2, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, Ta₂O₃, Ta₂O5, Y₂O₃, SrTiO₃, BaZrO, BaTiO₃ (BTO), (Ba, Sr)TiO₃ (BST), hafnium dioxide-alumina (HfO₂—Al₂O₃) alloy, other suitable high-k dielectric material, or combinations thereof. In one embodiment, the gate cut dielectric layers GCD has a depth that extended into STI region in a range of about 5 nm to about 60 nm.

As shown in the FIG. 4, the gate end dielectric layers GED are disposed at ends of the gate electrodes GE of the pass gate transistor PD-2 so as to electrically isolate the gate electrodes GE from adjacent SRAM cell CLi. In some embodiments, the gate end dielectric layers GED may be formed by, for example, patterning the portion of gate structures and the ILD layer to form openings, depositing a dielectric material in the openings, and then performing a planarization process (e.g., a CMP process) to remove excess dielectric material until top surfaces of the dummy gate structures and the ILD layer are exposed. In one embodiment, the gate end dielectric layers GED has a depth that extended into STI region in a range of about 5 nm to about 60 nm.

As shown in the FIG. 4, the interlayer dielectric layer ILD is disposed over the source/drain contacts. The interlayer dielectric layer ILD may comprise tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The interlayer dielectric layer ILD may be formed by PECVD (plasma enhanced CVD), FCVD (flowable CVD), or other suitable methods.

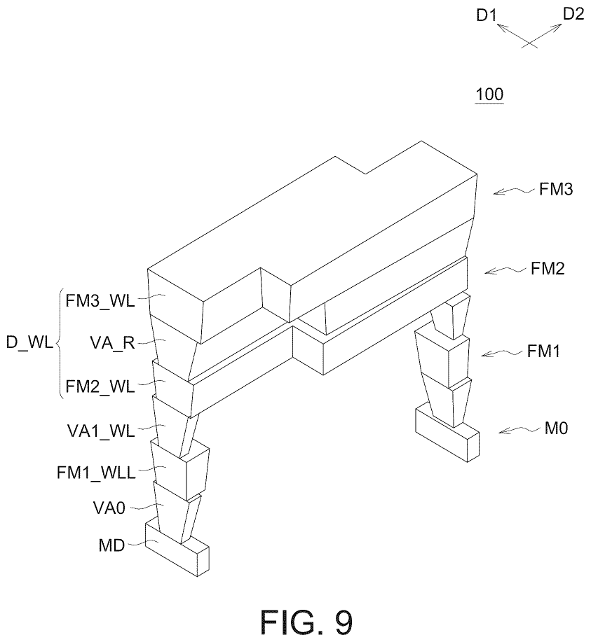

Referring to FIG. 9, an interconnection structure of a memory cell in the integrated circuit structure according to one embodiment is shown. The interconnection structure 100 includes a first level metal layer FM1, a second level metal layer FM2, a via line VA_R and a third level metal layer FM3. The first level metal layer FM1 is electrically connected to a memory cell CLi (as show in FIG. 3), and the first level metal layer FM1 includes two word-line landing lines FM1_WLL arranged along a second routing direction D2. The two word-line landing lines FM1_WLL are electrically to gate contacts MD of the contact metal layer M0 through the vias VA0.

In addition, the second-level metal layer FM2 is disposed on the first level metal layer FM1, and the second level metal layer FM2 includes a first word-line conductor FM2_WL extending along a second routing direction D2 that is different from the first routing direction D1. The via line VA_R is disposed on the first word-line conductor FM2_WL and extends along the second routing direction. The third level metal layer FM3 is disposed on the second level metal layer FM2, and the third level metal layer FM3 includes a second word-line conductor FM3_WL extending along the second routing direction D2, and the second word-line conductor FM3_WL, the via line VA_R and the first word-line conductor FM2_WL overlap along the second routing direction D2 to form a double-layered word-line conductor D_WL.

In other words, except for disposing the via line VA_R extending along the second wiring direction D2, there will be no additional bit-line conductors passing through the space between the first word-line conductor FM2_WL and the second word-line conductor FM3_WL. Therefore, the overlapping area of the bit-line conductors FM1_BL, FM1_BLB and the first word-line conductor FM2_WL and the overlapping area of the bit-line conductors FM1_BL, FM1_BLB and the second word-line conductor FM3_WL can be minimized to reduce the parasitic capacitance between the bit-line conductors FM1_BL, FM1_BLB and the first word-line conductor FM2_WL and the parasitic capacitance between the bit-line conductors FM1_BL, FM1_BLB and the second word-line conductor FM3_WL. In addition, the second word-line conductor FM3_WL is electrically connected to the first word-line conductor FM2_WL through the via line VA_R with large routing area so as to reduce the resistance of the double-layered word-line conductor D_WL.

The present disclosure is directed to an integrated circuit structure including a memory cell and an interconnection structure electrically connected to the memory cell. The interconnection structure includes a double-layered word-line conductor used to reduce the resistance of the word line, and the double-layered word-line conductor is arranged above the bit-line conductors, so that the overlapping areas of the double-layered word-line conductor and the bit-line conductors are reduced and the parasitic capacitance of the memory cell is reduced.

According to some embodiments of the present disclosure, an integrated circuit structure includes a memory cell and an interconnection structure electrically connected to the memory cell. The interconnection structure includes a first level metal layer, a second level metal layer, a via line, and a third level metal layer. The first level metal layer is disposed on the memory cell, and the first level metal layer includes a first bit-line conductor and a second bit-line conductor arranged along a first routing direction. The second level metal layer includes a first word-line conductor extending along a second routing direction different from the first routing direction. The via line is disposed on the first word-line conductor and extending along the second routing direction. The third level metal layer is disposed on the second level metal layer, and the third-level metal layer includes a second word-line conductor extending along the second routing direction, wherein the second word-line conductor, the via line and the first word-line conductor overlap along the second routing direction to form a double-layered word-line conductor.

According to some embodiments of the present disclosure, a method for forming a multi-layer interconnection structure of a memory cell includes the following steps. A first level metal layer is formed on the memory cell, and the first level metal layer includes a first bit-line conductor and a second bit-line conductor arranged along a first routing direction. A second level metal layer is formed on the first level metal layer, and the second level metal layer includes a first word-line conductor extending along a second routing direction different from the first routing direction. A via line is formed on the first word-line conductor, and the via line extends along the second routing direction. A third level metal layer is formed on the second-level metal layer, and the third level metal layer includes a second word-line conductor extending along the second routing direction, and the second word-line conductor, the via line and the first word-line conductor overlap along the second routing direction to form a double-layered word-line conductor.

According to some embodiments of the present disclosure, a double-layered word-line conductor includes a first word-line conductor, a via line, and a second word-line conductor. The first word-line conductor is disposed at a first layer and extending along a routing direction. The via line is disposed on the first word-line conductor and extends along the routing direction. The second word-line conductor is disposed at a second layer above the first layer and extends along the routing direction, wherein the second word-line conductor, the via line and the first word-line conductor overlap along the routing direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit structure, comprising:
a memory cell; and
an interconnection structure electrically connected to the memory cell, the interconnection structure comprising:
a first level metal layer disposed on the memory cell, the first level metal layer including a first bit-line conductor and a second bit-line conductor arranged along a first routing direction;
a second level metal layer disposed on the first level metal layer, the second level metal layer including a first word-line conductor extending along a second routing direction different from the first routing direction;
a via line disposed on the first word-line conductor and extending along the second routing direction; and
a third level metal layer disposed on the second level metal layer, the third-level metal layer including a second word-line conductor extending along the second routing direction, wherein the second word-line conductor, the via line and the first word-line conductor overlap along the second routing direction to form a double-layered word-line conductor.

2. The integrated circuit structure according to claim 1, wherein the memory cell has at least one static random-access memory (SRAM) cell, the SRAM cell comprises:
a first active region, following the first routing direction;
a second active region, following the first routing direction;
a third active region, following the first routing direction;
a fourth active region, following the first routing direction;
a first pull-up transistor, formed upon the third active region;
a second pull-up transistor, formed upon the fourth active region;
a first pass-gate transistor, formed upon the first active region;
a second pass-gate transistor, formed upon the second active region;
a first pull-down transistor, formed upon the first active region; and
a second pull-down transistor, formed upon the second active region;
wherein each of the at least one SRAM cell is formed on a N-well region of a P-type substrate.

3. The integrated circuit structure according to claim 2, wherein the first level metal layer further comprises:
two common voltage landing pads, located at two boundaries of the SRAM cell, electrically connected to a source node of the first pull-down transistor and a source node of the second pull-down transistor;
a word-line landing line, located at the two boundaries of the SRAM cell, and electrically connected to a gate node of the first pass-gate transistor and a gate node of the second pass-gate transistor;
a first local connection line and a first contact, used to make an electrical connection among a drain node of the first pull-up transistor, a drain node of the first pull-down transistor, a drain node of the first pass-gate transistor, a gate node of the second pull-up transistor and a gate node of the second pull-down transistor; and
a second local connection line and a second contact, used to make an electrical connection among a drain node of the second pull-up transistor, a drain node of the second pull-down transistor, a drain node of the second pass-gate transistor, a gate node of the first pull-up transistor and a gate node of the first pull-down transistor,
wherein the first bit-line conductor is electrically connected to the source node of the first pass-gate transistor and the second bit-line conductor is electrically connected to the source node of the second pass-gate transistor.

4. The integrated circuit structure according to claim 3, wherein the first level metal layer further comprises:
a first power supply voltage conductor, located in a middle of the SRAM cell and shared with another adjacent SRAM cell, and electrically connected to a source node of the first pull-up transistor and a source node of the second pull-up transistor.

5. The integrated circuit structure according to claim 3, wherein the first contact is located under the first local connection line and connected the first local connection line to the memory cell.

6. The integrated circuit structure according to claim 3, wherein the second contact is located under the first local connection line and connected the first local connection line to the memory cell.

7. The integrated circuit structure according to claim 3, wherein the second level metal layer further comprises:
two common voltage conductors, following the second routing direction and electrically connected to the two common voltage landing pads.

8. The integrated circuit structure according to claim 7, wherein the third level metal layer further comprises:
two common voltage conductor lines, following the second routing direction, and electrically connected to the two common voltage conductors.

9. The integrated circuit structure according to claim 3, wherein the first contact is electrically connected to the drain node of the first pull-down transistor and the gate node of the second pull-up transistor, and the second contact is electrically connected to the drain node of the second pull-down transistor and the gate node of the first pull-up transistor.

10. A method comprising:
forming a first level metal layer on a memory cell, the first level metal layer including a first bit-line conductor and a second bit-line conductor arranged along a first routing direction;
forming a second level metal layer on the first level metal layer, the second level metal layer including a first word-line conductor extending along a second routing direction different from the first routing direction;
forming a via line on the first word-line conductor, the via line extending along the second routing direction; and
forming a third level metal layer on the second-level metal layer, the third level metal layer including a second word-line conductor extending along the second routing direction, and the second word-line conductor, the via line and the first word-line conductor overlapping along the second routing direction to form a double-layered word-line conductor.

11. The method according to claim 10, wherein the memory cell has at least one static random-access memory (SRAM) cell, the SRAM cell comprises:
a first active region, following the first routing direction;
a second active region, following the first routing direction;
a third active region, following the first routing direction;
a fourth active region, following the first routing direction;
a first pull-up transistor, formed upon the third active region;
a second pull-up transistor, formed upon the fourth active region;
a first pass-gate transistor, formed upon the first active region;
a second pass-gate transistor, formed upon the second active region;
a first pull-down transistor, formed upon the first active region; and
a second pull-down transistor, formed upon the second active region;
wherein each of the at least one SRAM cell is formed on a N-well region of a P-type substrate.

12. The method according to claim 11, wherein forming the first level metal layer further comprises:
forming a first power supply voltage conductor, located in a middle of the SRAM cell and shared with another adjacent SRAM cell, and electrically connected to a source node of the first pull-up transistor and a source node of the second pull-up transistor;
forming two common voltage landing pads, located at two boundaries of the SRAM cell, electrically connected to a source node of the first pull-down transistor and a source node of the second pull-down transistor;
forming a word-line landing line, located at the two boundaries of the SRAM cell, and electrically connected to a gate node of the first pass-gate transistor and a gate node of the second pass-gate transistor;
forming a first local connection line and a first contact, used to make an electrical connection among a drain node of the first pull-up transistor, a drain node of the first pull-down transistor, a drain node of the first pass-gate transistor, a gate node of the second pull-up transistor and a gate node of the second pull-down transistor; and
forming a second local connection line and a second contact, used to make an electrical connection among a drain node of the second pull-up transistor, a drain node of the second pull-down transistor, a drain node of the second pass-gate transistor, a gate node of the first pull-up transistor and a gate node of the first pull-down transistor,
wherein the first bit-line conductor is electrically connected to the source node of the first pass-gate transistor and the second bit-line conductor is electrically connected to the source node of the second pass-gate transistor.

13. The method according to claim 12, wherein forming the first level metal layer further comprises:
forming a first power supply voltage conductor, located in a middle of the SRAM cell and shared with another adjacent SRAM cell, and electrically connected to a source node of the first pull-up transistor and a source node of the second pull-up transistor.

14. The method according to claim 12, wherein the first contact is located under the first local connection line and connected the first local connection line to the memory cell.

15. The method according to claim 12, wherein the second contact is located under the first local connection line and connected the first local connection line to the memory cell.

16. The method according to claim 12, wherein forming the second level metal layer further comprises:
forming two common voltage conductors, following the second routing direction and electrically connected to the two common voltage landing pads.

17. The method according to claim 16, wherein forming the third level metal layer further comprises:
forming two common voltage conductor lines, following the second routing direction, and electrically connected to the two common voltage conductors.

18. The method according to claim 12, wherein the first contact is electrically connected to the drain node of the first pull-down transistor and the gate node of the second pull-up transistor, and the second contact is electrically connected to the drain node of the second pull-down transistor and the gate node of the first pull-up transistor.

19. A device comprising:
a first word-line conductor, disposed at a first layer and extending along a routing direction;
a via line disposed on the first word-line conductor and extending along the routing direction; and
a second word-line conductor, disposed at a second layer above the first layer and extending along the routing direction, wherein the second word-line conductor, the via line and the first word-line conductor overlap along the routing direction.

20. The device according to claim 19, wherein the device is disposed on a memory cell.
